(19) United States
(12) Patent Application Publication
(10) Pub. No.: US 2024/0395452 A1
(43) Pub. Date: Nov. 28, 2024

(54) STACKED COUPLING COIL COMPONENT AND CIRCUIT BOARD HAVING THE SAME

(71) Applicant: TDK Corporation, Tokyo (JP)

(72) Inventors: Yuki HASHIMOTO, Tokyo (JP); Toshiyuki ABE, Tokyo (JP); Takeshi OKUMURA, Tokyo (JP); Tomonaga NISHIKAWA, Tokyo (JP); Masanori SUZUKI, Tokyo (JP)

(21) Appl. No.: 18/695,782

(22) PCT Filed: Jun. 27, 2022
(86) PCT No.: PCT/JP2022/025484

§ 371 Date: Mar. 26, 2024

(30) Foreign Application Priority Data
Sep. 27, 2021 (JP) 2021-157072

(51) Int. Cl. H01F 27/28; H01F 27/29; H05K 1/02; H05K 1/18

(52) U.S. Cl. CPC H01F 27/2804; H01F 27/292; H05K 1/0213; H05K 1/181; H01F 2027/2809

(57) ABSTRACT

To provide a stacked coupling coil component capable of achieving a desired coupling coefficient while suppressing the height of the component. A stacked coupling coil component 1 has conductor layers L1, L3, and L5 respectively including spiral coils 11 to 13, conductor layers L2, L4, and L6 respectively including spiral coils 21 to 23, and a conductor layer L7 including spiral coils 31 and 41 which are disposed at mutually different planar positions. The spiral coils 11 to 13 and 21 to 23 overlap one another. The spiral coils 11 to 13 and 31 are connected in series between terminal electrodes E1 and E2, the spiral coils 21 to 23 and 41 are connected in series between terminal electrodes E4 and E3. This allows adjustment of a coupling coefficient, making it possible to achieve a desired coupling coefficient while suppressing the height of the component.

### TECHNICAL FIELD

The present invention relates to a stacked coupling coil component having a structure in which a plurality of conductor layers are stacked and a circuit board having the stacked coupling coil component.

### BACKGROUND ART

Patent Document 1 discloses a stacked coupling coil component having a structure in which a plurality of conductor layers are stacked. The stacked coupling coil component disclosed in Patent Document 1 has four conductor layers, and spiral coils connected to one line and spiral coils connected to the other line are alternately stacked. As a result, strong magnetic coupling can be achieved between a pair of lines.

### CITATION LIST

### Patent Document

[Patent Document 1] JP 2017-174888A

### SUMMARY OF THE INVENTION

### Problem to be Solved by the Invention

However, when the stacked coupling coil component is used as an LC filter for removing unnecessary band noise, a coupling coefficient to be used differs depending on required frequency characteristics and, in some case, there occurs a need to reduce the coupling coefficient to some extent. For reducing the coupling coefficient, it can be considered to increase a distance between the spiral coils connected to one line and spiral coils connected to the other line; however, this disadvantageously increases the height of the component.

It is therefore an object of the present invention to provide a stacked coupling coil component capable of achieving a desired coupling coefficient while suppressing the height thereof and a circuit board having such a stacked coupling coil component.

### Means for Solving the Problem

A stacked coupling coil component according to the present invention has an element body embedding therein a plurality of stacked conductor layers and first to fourth terminal electrodes formed on the surface of the element body. The plurality of conductor layers include a first conductor layer having a first spiral coil, a second conductor layer having a second spiral coil, and a third conductor layer having third and fourth spiral coils provided at mutually different planar positions. The first and second spiral coils overlap each other as viewed in the stacking direction, the first and third spiral coils are connected in series between the first and second terminal electrodes, and the second and fourth spiral coils are connected in series between the fourth and third terminal electrodes.

According to the present invention, a coupling coefficient can be adjusted by the number of sets of the first and second conductor layers and the number of the third conductor layers, making it possible to achieve a desired coupling coefficient while suppressing the height of the component.

In the present invention, a plurality of the first conductor layers and a plurality of the second conductor layers may be alternately stacked. This allows coupling between the first and second spiral coils to be enhanced.

In the present invention, a plurality of the third conductor layers may be stacked. This can reduce a coupling coefficient. In this case, the third spiral coils formed respectively in at least two of the plurality of third conductor layers may be connected in parallel, and the fourth spiral coils formed respectively in at least two of the plurality of third conductor layers may be connected in parallel. With this configuration, even when the number of the first or second conductor layer is odd, and the number of the third conductor layers is even, the outer peripheral ends of the respective third and fourth spiral coils can be connected respectively to the second and third terminal electrodes.

In the present invention, the first spiral coil may be wound in a first direction from the first terminal electrode to the second terminal electrode, and the second spiral coil may be wound in a second direction opposite to the first direction from the fourth terminal electrode to the third terminal electrode. With this configuration, it is possible to cut off a differential signal component to be input to the first and fourth terminal electrodes and to allow passage of a common mode noise component to be input to the first and fourth terminal electrodes. In this case, the third spiral coil may be wound in the first direction from the first terminal electrode to the second terminal electrode, and the fourth spiral coil may be wound in the second direction from the fourth terminal electrode to the third terminal electrode. With this configuration, a coupling coefficient can be further reduced by the third conductor layer.

A circuit board according to the present invention includes: a substrate having first and second signal lines and a ground pattern; and the above-described stacked coupling coil component mounted on the substrate. The first and fourth terminal electrodes of the stacked coupling coil component are connected respectively to first and second signal lines, and the second and third terminal electrodes of the stacked coupling coil component are connected in common to the ground pattern through a capacitor. This allows a common mode noise component to flow in the ground pattern without attenuating a differential signal component to be transmitted to the first and second signal lines.

### Advantageous Effects of the Invention

As described above, according to the present invention, there can be provided a stacked coupling coil component capable of achieving a desired coupling coefficient while suppressing the height of the component and a circuit board having such a stacked coupling coil component.

### BRIEF DESCRIPTION OF THE DRAWINGS

FIG. 1 is a schematic perspective view illustrating the outer appearance of a stacked coupling coil component 1 according to one embodiment of the present invention.

FIG. 2 is a developed view for explaining a first example of pattern shapes of the plurality of conductor layers embedded in the element body 2.

FIG. 3 is a cross-sectional view for explaining the first example of pattern shapes of the plurality of conductor layers embedded in the element body 2.

FIG. 4 is an equivalent circuit diagram of the stacked coupling coil component 1 according to a first example.

FIG. 5 is a circuit diagram of a circuit board 4 on which the stacked coupling coil component 1 is mounted.

FIG. 6 is a developed view for explaining a second example of pattern shapes of the plurality of conductor layers embedded in the element body 2.

FIG. 7 is a cross-sectional view for explaining the second example of pattern shapes of the plurality of conductor layers embedded in the element body 2.

FIG. 8 is an equivalent circuit diagram of the stacked coupling coil component 1 according to a second example.

FIG. 9 is a cross-sectional view for explaining a first modification of the pattern shape shown in FIG. 7.

FIG. 10 is a cross-sectional view for explaining a second modification of the pattern shape shown in FIG. 7.

FIG. 11 is a developed view for explaining a third example of pattern shapes of the plurality of conductor layers embedded in the element body 2.

FIG. 12 is a cross-sectional view for explaining the third example of pattern shapes of the plurality of conductor layers embedded in the element body 2.

FIG. 13 is an equivalent circuit diagram of the stacked coupling coil component 1 according to a third example.

### MODE FOR CARRYING OUT THE INVENTION

Hereinafter, preferred embodiments of the present invention will be described in detail with reference to the accompanying drawings.

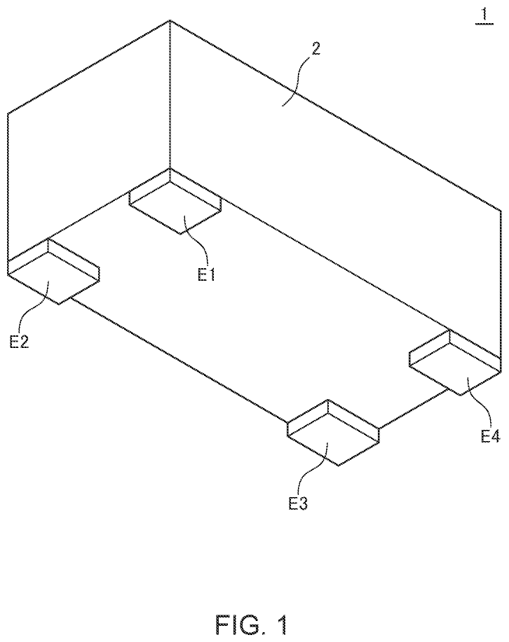

FIG. 1 is a schematic perspective view illustrating the outer appearance of a stacked coupling coil component 1 according to one embodiment of the present invention.

As illustrated in FIG. 1, the stacked coupling coil component 1 according to the present embodiment includes an element body 2 and terminal electrodes E1 to E4 formed on the surface of the element body 2. As will be described later, a plurality of conductor layers are stacked inside the element body 2, and a spiral coil is formed in each of the conductor layers. The element body 2 is a composite member containing a metallic magnetic filler made of iron (Fe), a permalloy-based material, or the like and a resin binder.

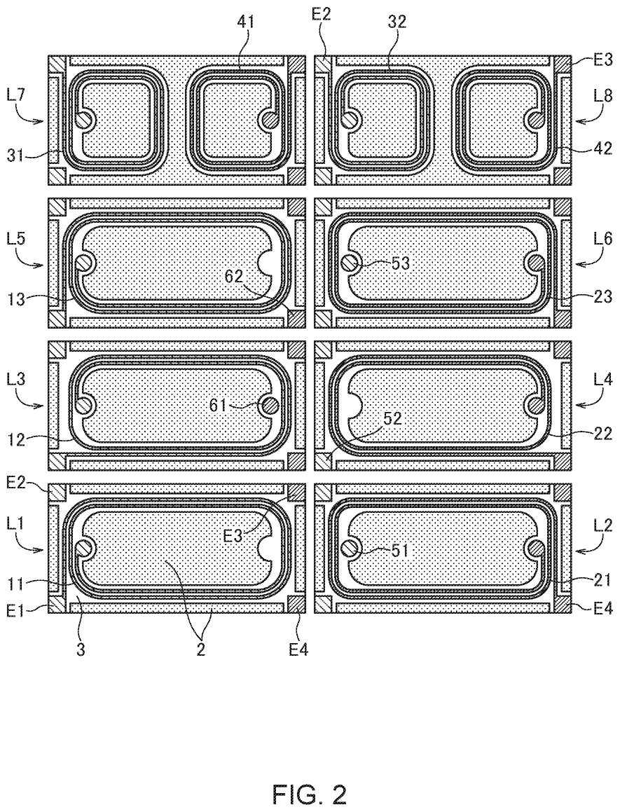

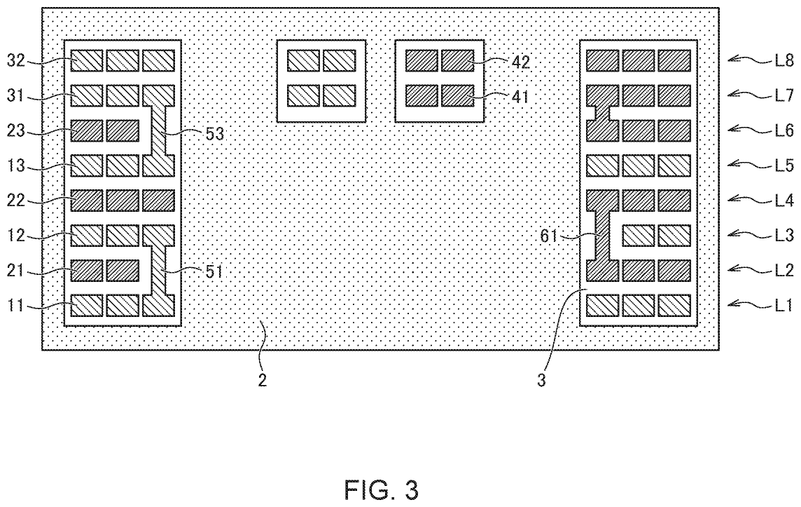

FIGS. 2 and 3 are, respectively, a developed view and a cross-sectional view for explaining a first example of pattern shapes of the plurality of conductor layers embedded in the element body 2.

As illustrated in FIGS. 2 and 3, the stacked coupling coil component 1 according to the present embodiment has eight conductor layers L1 to L8 stacked in this order. The surface of the conductor pattern formed in each of the conductor layers L1 to L8 is covered with an insulating resin layer 3. In the first example illustrated in FIGS. 2 and 3, the conductor layers L1, L3, and L5 have spiral coils 11, 12, and 13, respectively, the conductor layers L2, L4, and L6 have spiral coils 21, 22, and 23, respectively, the conductor layer L7 has spiral coils 31 and 41, and the conductor layer L8 has spiral coils 32 and 42. The spiral coils 11 to 13 and the spiral coils 21 to 23 overlap each other as viewed in the stacking direction. The spiral coils 31 and 41 are provided at mutually different planar positions, and the spiral coils 32 and 42 are provided at mutually different planar positions.

The outer peripheral end of the spiral coil 11 provided in the conductor layer L1 is connected to the terminal electrode E1. The inner peripheral end of the spiral coil 11 is connected to the inner peripheral end of the spiral coil 12 provided in the conductor layer L3 through a relay pattern 51 provided in the conductor layer L2. The outer peripheral end of the spiral coil 12 is connected to the outer peripheral end of the spiral coil 3 provided in the conductor layer L5 through a relay pattern 52 provided in the conductor layer L4. The inner peripheral end of the spiral coil 13 is connected in common to the inner peripheral ends of the respective spiral coils 31 and 32 provided in the respective conductor layers L7 and L8 through a relay pattern 53 provided in the conductor layer L6. The outer peripheral ends of the respective spiral coils 31 and 32 are connected to the terminal electrode E2.

The outer peripheral end of the spiral coil 21 provided in the conductor layer L2 is connected to the terminal electrode E4. The inner peripheral end of the spiral coil 21 is connected to the inner peripheral end of the spiral coil 22 provided in the conductor layer L4 through a relay pattern 61 provided in the conductor layer L3. The outer peripheral end of the spiral coil 22 is connected to the outer peripheral end of the spiral coil 23 provided in the conductor layer L6 through a relay pattern 62 provided in the conductor layer L5. The inner peripheral end of the spiral coil 23 is connected in common to the inner peripheral ends of the respective spiral coils 41 and 42 provided in the respective conductor layers L7 and L8. The outer peripheral ends of the respective spiral coils 41 and 42 are connected to the terminal electrode E3.

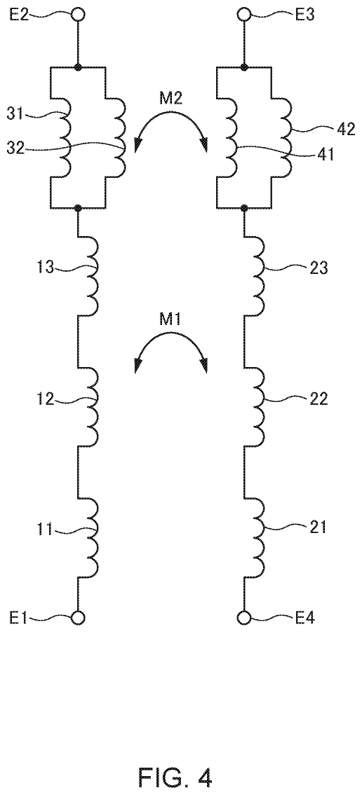

With the above configuration, as illustrated in FIG. 4 which is an equivalent circuit diagram, the spiral coils 11 to 13 and the parallel-connected spiral coils 31 and 32 are connected in series between the terminal electrodes E1 and E2. Further, the spiral coils 21 to 23 and the parallel-connected spiral coils 41 and 42 are connected in series between the terminal electrodes E4 and E3. The spiral coils 11 to 13 and the spiral coils 21 to 23 are alternately stacked so as to overlap each other in the stacking direction, so that a strong magnetic coupling M1 occurs between the spiral coils 11 to 13 and the spiral coils 21 to 23. On the other hand, the spiral coils 31, 32 and the spiral coils 41, 42 do not overlap each other in the stacking direction and are provided at mutually different planar positions, so that a weak magnetic coupling M2 occurs between the spiral coils 31, 32 and the spiral coils 41, 42. The spiral coils 11 to 13 and the spiral coils 41, 42 partly overlap each other, so that a magnetic coupling occurs therebetween. Similarly, the spiral coils 21 to 23 and the spiral coils 31, 32 partly overlap each other, so that a magnetic coupling occurs therebetween.

Assuming that the terminal electrodes E1 and E2 are set as a starting point and an end point, respectively, the spiral coils 11 to 13, 31, and 32 are wound in the right-hand direction (clockwise direction). On the other hand, assuming that the terminal electrodes E4 and E3 are set as a starting point and an end point, respectively, the spiral coils 21 to 23, 41, and 42 are wound in the left-hand direction (counterclockwise direction). Thus, when the terminal electrodes E1 and E4 are connected to a pair of differential signal lines, a differential signal component is cut off since the spiral coils 11 to 13 and the spiral coils 21 to 23 mutually strengthen magnetic flux, while a common mode noise component is output to the terminal electrodes E2 and E3 since the spiral coils 11 to 13 and the spiral coils 21 to 23 mutually cancel magnetic flux. The spiral coils 31, 32 and the spiral coils 41, 42 mutually cancel magnetic flux caused by the differential signal component and mutually strengthen magnetic flux caused by the common mode noise component; however, a coupling degree therebetween is 1/10 or less of a coupling degree between the spiral coils 11 to 13 and the spiral coils 21 to 23, thus exhibiting substantially no effect of cutting off the common mode noise component.

Specifically, an inductance value obtained by the spiral coils 11 to 13 and 21 to 23 is 1.5 μH, an inductance value obtained by the spiral coils 31, 32, 41, and 42 is 1.3 μH, and the entire coupling coefficient is 0.96. The coupling coefficient can also be adjusted by shifting the planar position of the spiral coils 11 to 13 and the planar position of the spiral coils 21 to 23 from each other.

Although the conductor layer L8 having the spiral coils 32 and 42 may be omitted, a DC resistance is reduced by connecting the spiral coils 31 and 32 in parallel and connecting the spiral coils 41 and 42 in parallel. On the other hand, when the spiral coils 31 and 32 are connected in series, and the spiral coils 41 and 42 are connected in series, the number of series connections of the spiral coil becomes odd (5), so that the spiral coils 32 and 42 are terminated at the inner peripheral end side, making lead-out to the terminal electrodes E2 and E3 difficult. Therefore, in this case, it is preferable to make the number of series connections of the spiral coil even by adding one conductor layer.

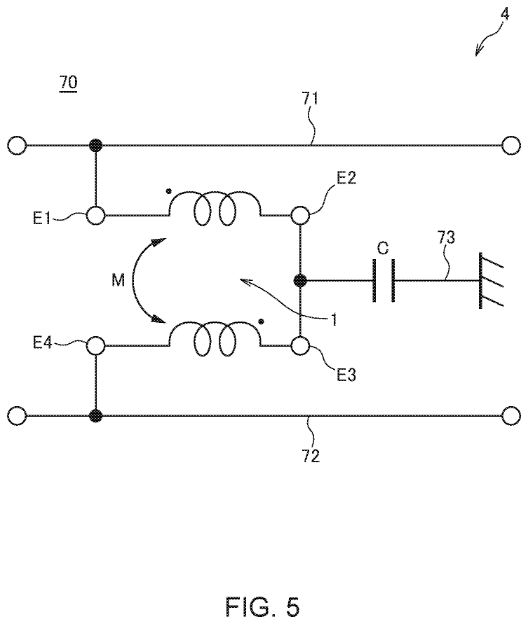

FIG. 5 is a circuit diagram of a circuit board 4 on which the stacked coupling coil component 1 according to the present embodiment is mounted.

As illustrated in FIG. 5, a pair of signal lines 71 and 72 and a ground pattern 73 are provided on a substrate 70. The terminal electrodes E1 and E4 of the stacking coupling coil component 1 are connected respectively to the signal lines 71 and 72, and the terminal electrodes E2 and E3 of the stacking coupling coil component 1 are connected in common to the ground pattern 73 through a capacitor C. This constitutes an LC filter, thus allowing the common mode noise component to flow in the ground pattern 73 without attenuating the differential signal component flowing in the pair of signal lines 71 and 72. The frequency characteristics of the LC filter can be adjusted by the inductance and coupling coefficient of the stacking coupling coil component 1 and the capacitance of the capacitor C. With the configuration illustrated in FIGS. 2 to 4, a strong magnetic coupling occurs in the conductor layers L1 to L6, while the magnetic coupling becomes weak in the conductor layers L7 and L8, so that it is possible to achieve a coupling degree M corresponding to frequency characteristics required for the LC filter while ensuring sufficient inductance.

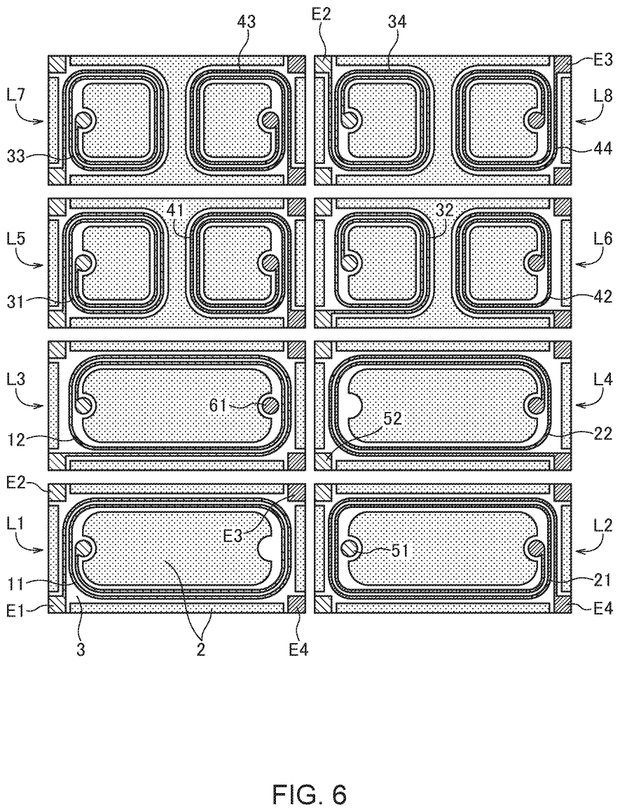

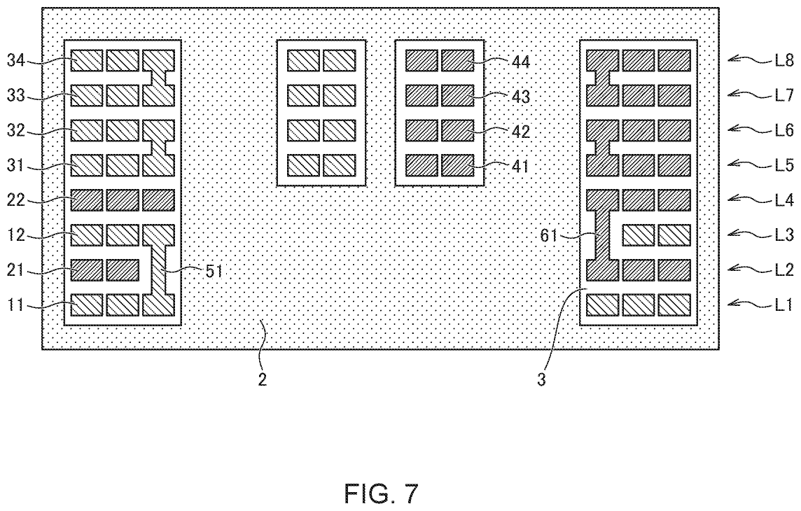

FIGS. 6 and 7 are, respectively, a developed view and a cross-sectional view for explaining a second example of pattern shapes of the plurality of conductor layers embedded in the element body 2.

In the second example illustrated in FIGS. 6 and 7, the conductor layers L1 and L3 have spiral coils 11 and 12, respectively, the conductor layers L2 and L4 have spiral coils 21 and 22, respectively, the conductor layer L5 has spiral coils 31 and 41, the conductor layer L6 has spiral coils 32 and 42, the conductor layer L7 has spiral coils 33 and 34, and the conductor layer L8 has spiral coils 34 and 44. The spiral coils 11 and 12 and the spiral coils 21 and 22 overlap each other as viewed in the stacking direction. The spiral coils 31 and 41 are provided at mutually different planar positions, the spiral coils 32) and 42 are provided at mutually different planar positions, the spiral coils 33 and 43 are provided at mutually different planar positions, and the spiral coils 34 and 44 are provided at mutually different planar positions. Further, the spiral coils 31 to 34 overlap one another in the stacking direction, and the spiral coils 41 to 44 overlap one another in the stacking direction.

The outer peripheral end of the spiral coil 11 provided in the conductor layer L1 is connected to the terminal electrode E1. The inner peripheral end of the spiral coil 11 is connected to the inner peripheral end of the spiral coil 12 provided in the conductor layer L3 through a relay pattern 51 provided in the conductor layer L2. The outer peripheral end of the spiral coil 12 is connected to the outer peripheral end of the spiral coil 31 provided in the conductor layer L5 through a relay pattern 52 provided in the conductor layer L4. The inner peripheral end of the spiral coil 31 is connected to the inner peripheral end of the spiral coil 32 provided in the conductor layer L6. The outer peripheral end of the spiral coil 32 is connected to the outer peripheral end of the spiral coil 33 provided in the conductor layer L7. The inner peripheral end of the spiral coil 33 is connected to the inner peripheral end of the spiral coil 34 provided in the conductor layer L8. The outer peripheral end of the spiral coil 34 is connected to the terminal electrode E2.

The outer peripheral end of the spiral coil 21 provided in the conductor layer L2 is connected to the terminal electrode E4. The inner peripheral end of the spiral coil 21 is connected to the inner peripheral end of the spiral coil 22 provided in the conductor layer L4 through a relay pattern 61 provided in the conductor layer L3. The outer peripheral end of the spiral coil 22 is connected to the outer peripheral end of the spiral coil 41 provided in the conductor layer L5. The inner peripheral end of the spiral coil 41 is connected to the inner peripheral end of the spiral coil 42 provided in the conductor layer L6. The outer peripheral end of the spiral coil 42 is connected to the outer peripheral end of the spiral coil 43 provided in the conductor layer L7. The inner peripheral end of the spiral coil 43 is connected to the inner peripheral end of the spiral coil 44 provided in the conductor layer L8. The outer peripheral end of the spiral coil 44 is connected to the terminal electrode E3.

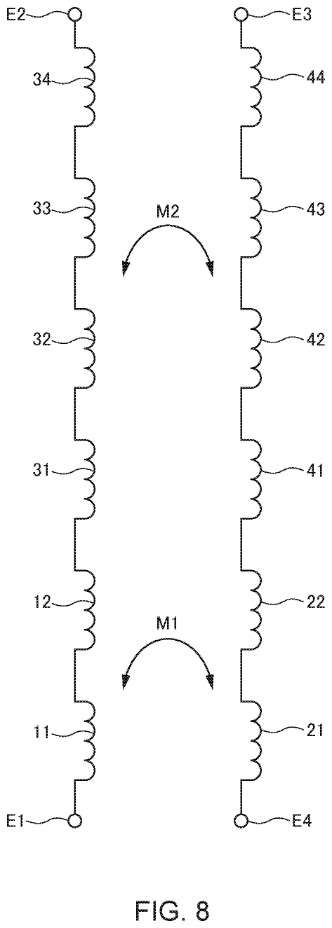

With the above configuration, as illustrated in FIG. 8 which is an equivalent circuit diagram, the spiral coils 11, 12, and 31 to 34 are connected in series between the terminal electrodes E1 and E2. Further, the spiral coils 21, 22, and 41 to 44 are connected in series between the terminal electrodes E4 and E3. The spiral coils 11, 12 and the spiral coils 21, 22 are alternately stacked so as to overlap each other in the stacking direction, so that a strong magnetic coupling M1 occurs between the spiral coils 11, 12 and the spiral coils 21, 22. On the other hand, the spiral coils 31 to 34 and the spiral coils 41 to 44 do not overlap each other in the stacking direction and are provided at mutually different planar positions, so that a weak magnetic coupling M2 occurs between the spiral coils 31 to 34 and the spiral coils 41 to 44. The spiral coils 11, 12 and the spiral coils 41 to 44 partly overlap each other, so that a magnetic coupling occurs therebetween. Similarly, the spiral coils 21, 22 and the spiral coils 31 to 34 partly overlap each other, so that a magnetic coupling occurs therebetween.

Assuming that the terminal electrodes E1 and E2 are set as a starting point and an end point, respectively, the spiral coils 11, 12, and 31 to 34 are wound in the right-hand direction (clockwise direction). On the other hand, assuming that the terminal electrodes E4 and E3 are set as a starting point and an end point, respectively, the spiral coils 21, 22, and 41 to 44 are wound in the left-hand direction (counterclockwise direction). Thus, when the terminal electrodes E1 and E4 are connected to a pair of differential signal lines, a differential signal component is cut off since the spiral coils 11, 12 and the spiral coils 21, 22 mutually strengthen magnetic flux, while a common mode noise component is output to the terminal electrodes E2 and E3 since the spiral coils 11, 12 and the spiral coils 21, 22 mutually cancel magnetic flux. The spiral coils 31 to 34 and the spiral coils 41 to 44 mutually cancel magnetic flux caused by the differential signal component and mutually strengthen magnetic flux caused by the common mode noise component; however, a coupling degree therebetween is sufficiently smaller than a coupling degree between the spiral coils 11, 12 and the spiral coils 21, 22, exhibiting substantially no effect of cutting off the common mode noise component.

Thus, with the configuration illustrated in FIGS. 6 to 8, a strong magnetic coupling occurs in the conductor layers L1 to L4, while the magnetic coupling becomes weak in the conductor layers L5 to L8, so that it is possible to reduce the entire coupling degree M more than in the configuration illustrated in FIGS. 2 to 4 while ensuring sufficient inductance.

Specifically, an inductance value obtained by the spiral coils 11, 12, 21, and 22 is 1.0 μH, an inductance value obtained by the spiral coils 31 to 34 and 41 to 44 is 1.8 μH, and the entire coupling degree is 0.63. The coupling coefficient can also be adjusted by shifting the planar position of the spiral coils 11, 12 and the planar position of the spiral coils 21, 22 from each other.

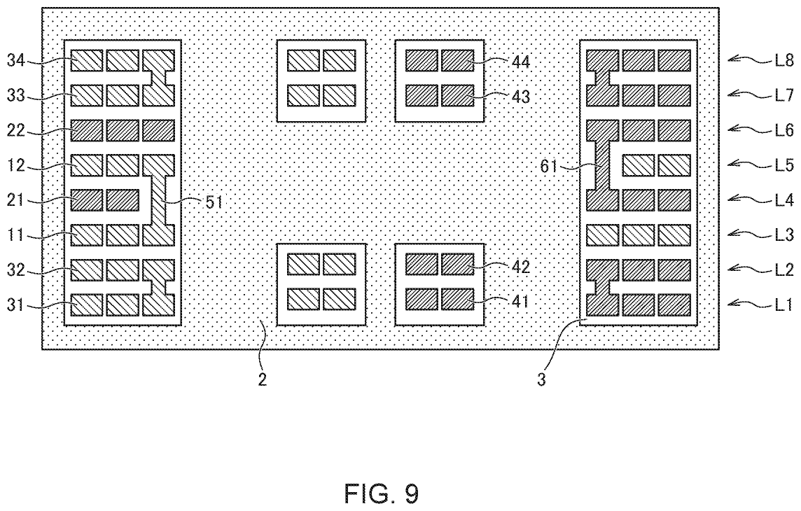

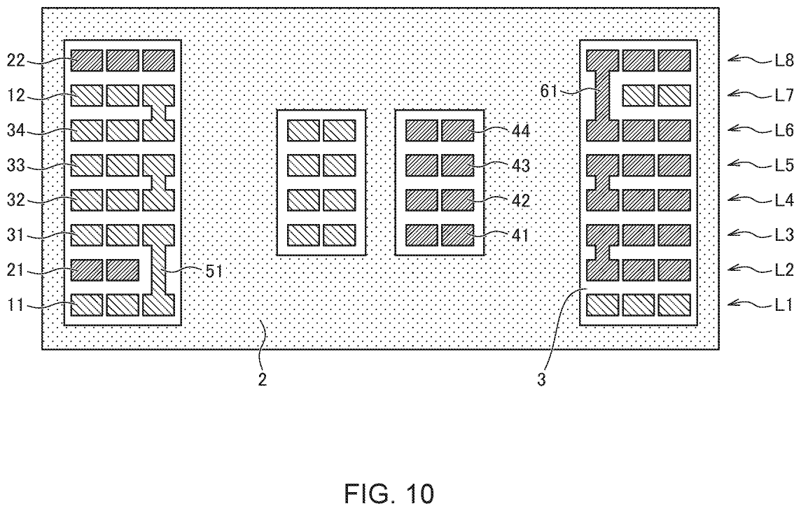

In the example illustrated in FIGS. 6 to 8, the spiral coils 11, 12, 21, and 22 between which a strong magnetic coupling occurs are provided in the conductor layers L1 to L4, and the spiral coils 31 to 34, 41 to 44 between which a weak magnetic field occurs are provided in the conductor layers L5 and L6; however, the positional relation between the spiral coils having a strong magnetic coupling and the spiral coils having a weak magnetic coupling can optionally be set. For example, as illustrated in FIG. 9, the spiral coils having a strong magnetic coupling may be provided in the conductor layers L3 to L6, and the spiral coils having a weak magnetic coupling may be provided in the conductor layers L1, L2, L7, and L8, or, as illustrated in FIG. 10, the spiral coils having a strong magnetic coupling may be provided in the conductor layers L1, L2, L7, and L8, and the spiral coils having a weak magnetic coupling may be provided in the conductor layers L3 to L6.

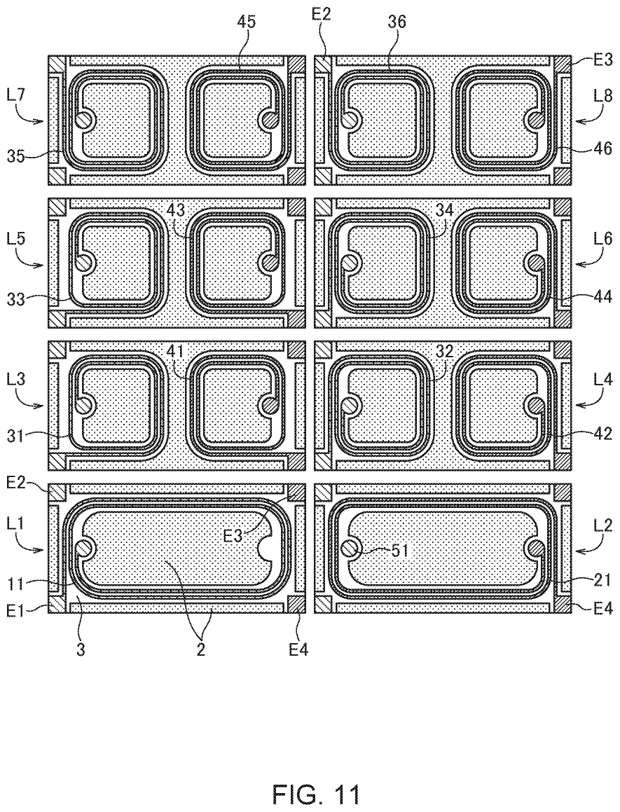

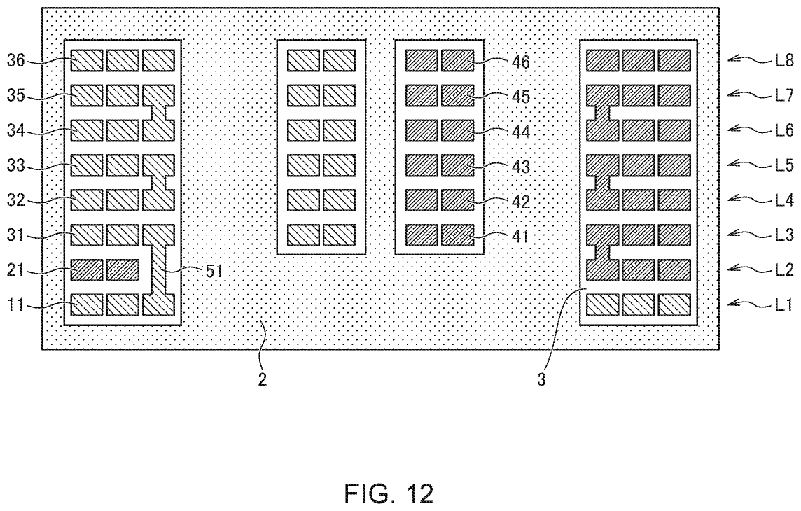

FIGS. 11 and 12 are, respectively, a developed view and a cross-sectional view for explaining a third example of pattern shapes of the plurality of conductor layers embedded in the element body 2.

In the third example illustrated in FIGS. 11 and 12, the conductor layer L1 has a spiral coil 11, the conductor layer L2 has a spiral coil 21, the conductor layer L3 has spiral coils 31 and 41, the conductor layer L4 has spiral coils 32 and 42, the conductor layer L5 has spiral coils 33 and 43, the conductor layer L6 has spiral coils 34 and 44, the conductor layer L7 has spiral coils 35 and 45, and the conductor layer L8 has spiral coils 36 and 46. The spiral coils 11 and 21 overlap each other as viewed in the stacking direction. The spiral coils 31 and 41 are provided at mutually different planar positions, the spiral coils 32 and 42 are provided at mutually different planar positions, the spiral coils 33 and 43 are provided at mutually different planar positions, and the spiral coils 34 and 44 are provided at mutually different planar positions, the spiral coils 35 and 45 are provided at mutually different planar positions, and the spiral coils 36 and 46 are provided at mutually different planar positions. Further, the spiral coils 31 to 36 overlap one another in the stacking direction, and the spiral coils 41 to 46 overlap one another in the stacking direction.

The outer peripheral end of the spiral coil 11 provided in the conductor layer L1 is connected to the terminal electrode E1. The inner peripheral end of the spiral coil 11 is connected to the inner peripheral end of the spiral coil 31 provided in the conductor layer L3 through a relay pattern 51 provided in the conductor layer L2. The outer peripheral end of the spiral coil 31 is connected to the outer peripheral end of the spiral coil 32 provided in the conductor layer L4. The inner peripheral end of the spiral coil 32 is connected to the inner peripheral end of the spiral coil 33 provided in the conductor layer L5. The outer peripheral end of the spiral coil 33 is connected to the outer peripheral end of the spiral coil 34 provided in the conductor layer L6. The inner peripheral end of the spiral coil 34 is connected in common to the inner peripheral ends of the respective spiral coils 35 and 36 provided respectively in the conductor layers L7 and L8. The outer peripheral ends of the respective spiral coils 35 and 36 are connected to the terminal electrode E2.

The outer peripheral end of the spiral coil 21 provided in the conductor layer L2 is connected to the terminal electrode E4. The inner peripheral end of the spiral coil 21 is connected to the inner peripheral end of the spiral coil 41 provided in the conductor layer L3. The outer peripheral end of the spiral coil 41 is connected to the outer peripheral end of the spiral coil 42 provided in the conductor layer L4. The inner peripheral end of the spiral coil 42 is connected to the inner peripheral end of the spiral coil 43 provided in the conductor layer L5. The outer peripheral end of the spiral coil 43 is connected to the outer peripheral end of the spiral coil 44 provided in the conductor layer L6. The inner peripheral end of the spiral coil 44 is connected in common to the inner peripheral ends of the respective spiral coils 45 and 46 provided respectively in the conductor layers L7 and L8. The outer peripheral ends of the respective spiral coils 45 and 46 are connected to the terminal electrode E3.

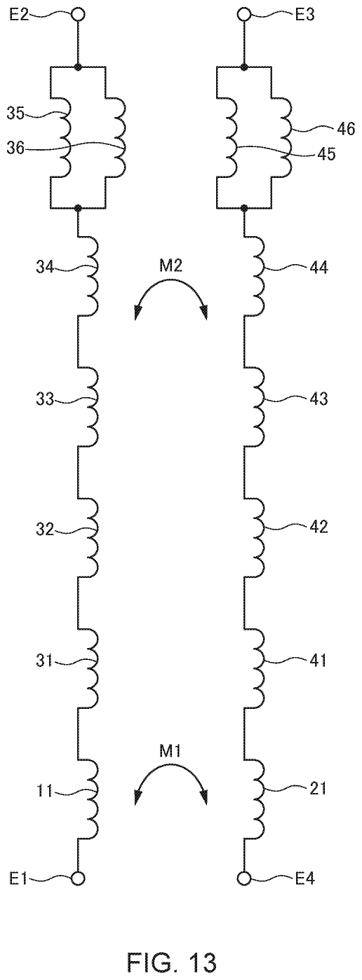

With the above configuration, as illustrated in FIG. 13 which is an equivalent circuit diagram, the spiral coils 11, 31 to 34 and the parallel-connected spiral coils 35 and 36 are connected in series between the terminal electrodes E1 and E2. Further, the spiral coils 21, 41 to 44 and parallel-connected spiral coils 45 and 46 are connected in series between the terminal electrodes E4 and E3. The spiral coils 11 and 21 overlap each other in the stacking direction, so that a strong magnetic coupling M1 occurs between the spiral coils 11 and 21. On the other hand, the spiral coils 31 to 36 and the spiral coils 41 to 46 do not overlap each other in the stacking direction and are provided at mutually different planar positions, so that a weak magnetic coupling M2 occurs between the spiral coils 31 to 36 and the spiral coils 41 to 46.

Assuming that the terminal electrodes E1 and E2 are set as a starting point and an end point, respectively, the spiral coils 11 and 31 to 36 are wound in the right-hand direction (clockwise direction). On the other hand, assuming that the terminal electrodes E4 and E3 are set as a starting point and an end point, respectively, the spiral coils 21 and 41 to 46 are wound in the left-hand direction (counterclockwise direction). Thus, when the terminal electrodes E1 and E4 are connected to a pair of differential signal lines, a differential signal component is cut off since the spiral coils 11 and 21 mutually strengthen magnetic flux, while a common mode noise component is output to the terminal electrodes E2 and E3 since the spiral coils 11 and 21 mutually cancel magnetic flux. The spiral coils 31 to 36 and the spiral coils 41 to 46 mutually cancel magnetic flux caused by the differential signal component and mutually strengthen magnetic flux caused by the common mode noise component; however, a coupling degree therebetween is sufficiently smaller than a coupling degree between the spiral coils 11 and 21, thus exhibiting substantially no effect of cutting off the common mode noise component.

Thus, with the configuration illustrated in FIGS. 11 to 13, a strong magnetic coupling occurs in the conductor layers L1 and L2, while the magnetic coupling becomes weak in the conductor layers L3 to L8, so that it is possible to reduce the entire coupling degree M more than in the configuration illustrated in FIGS. 6 to 8 while ensuring sufficient inductance.

Specifically, an inductance value obtained by the spiral coils 11 and 21 is 0.5 μH, an inductance value obtained by the spiral coils 31 to 36 and 41 to 46 is 2.6 μH, and the entire coupling coefficient is 0.33. The coupling coefficient can also be adjusted by shifting the planar position of the spiral coil 11 and the planar position of the spiral coil 21 from each other.

Although the conductor layer L8 having the spiral coils 36 and 46 may be omitted, a DC resistance is reduced by connecting the spiral coils 35 and 36 in parallel and connecting the spiral coils 45 and 46 in parallel. On the other hand, when the spiral coils 35 and 36 are connected in series, and the spiral coils 45 and 46 are connected in series, the number of series connections of the spiral coil becomes odd (7), so that the spiral coils 36 and 46 are terminated at the inner peripheral end side, making lead-out to the terminal electrodes E2 and E3 difficult. Therefore, in this case, it is preferable to make the number of series connections of the spiral coil even by adding one conductor layer.

While the preferred embodiment of the present disclosure has been described, the present disclosure is not limited to the above embodiment, and various modifications may be made within the scope of the present disclosure, and all such modifications are included in the present disclosure.

### REFERENCE SIGNS LIST

1 stacked coupling coil component
2 element body
3 insulating resin layer
4 circuit board
11-13, 21-23, 31-36, 41-46 spiral coil
51-53, 61, 62 relay pattern
70 substrate
71, 72 signal line
73 ground pattern
C capacitor
E1-E4 terminal electrode
L1-L8 conductor layer

1-7. (canceled)

8. A coupling coil comprising:
an element body including a plurality of stacked conductor layers,
the plurality of conductor layers comprising at least one first conductor layer having at least one first spiral coil, at least one second conductor layer having at least one second spiral coil, and at least one third conductor layer having at least one third spiral coil and at least one fourth spiral coil,
the at least one first spiral coil and the at least one second spiral coil overlapping each other as viewed in a stacking direction,
the at least one third spiral coil and the at least one fourth spiral coil being disposed on different planar positions in the at least one third conductor layer; and
a first terminal electrode, a second terminal electrode, a third terminal electrode, and a fourth terminal electrode formed on a surface of the element body,
wherein the at least one first spiral coil and the at least one third spiral coil are connected in series between the first terminal electrode and the second terminal electrode, and
wherein the at least one second spiral coil and the at least one fourth spiral coil are connected in series between the fourth terminal electrode and the third terminal electrode.

9. The coupling coil as claimed in claim 8, wherein the at least one first conductor layer comprises a plurality of conductor layers, and the at least one second conductor layer comprises a plurality of the conductor layers,
each of the plurality of conductor layers of the at least one first conductor layer and the plurality of conductor layers of the at least one second conductor layer being alternately stacked each other.

10. The coupling coil as claimed in claim 8, wherein the at least one third conductor layer comprises one or more conductor layers.

11. The coupling coil as claimed in claim 9, wherein the at least one third conductor layer comprises one or more conductor layers.

12. The coupling coil as claimed in claim 10,
wherein the at least one third spiral coil comprises one or more spiral coils formed respectively in at least two conductor layers of the one or more conductor layers of the at least one third conductor layer, each of the one or more spiral coils of the at least one third spiral coil being connected in parallel to each other, and
wherein the at least one fourth spiral coil comprises one or more spiral coils formed respectively in at least two conductor layers of the one or more conductor layers of the at least one third conductor layer, each of the one or more spiral coils of the at least one fourth spiral coil being connected in parallel to each other.

13. The coupling coil as claimed in claim 11,
wherein the at least one third spiral coil comprises one or more spiral coils formed respectively in at least two conductor layers of the one or more conductor layers of the at least one third conductor layer, each of the one or more spiral coils of the at least one third spiral coil being connected in parallel to each other, and
wherein the at least one fourth spiral coil comprises one or more spiral coils formed respectively in at least two conductor layers of the one or more conductor layers of the at least one third conductor layer, each of the one or more spiral coils of the at least one fourth spiral coil being connected in parallel to each other.

14. The coupling coil as claimed in claim 8,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

15. The coupling coil as claimed in claim 9,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

16. The coupling coil as claimed in claim 10,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

17. The coupling coil as claimed in claim 11,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

18. The coupling coil as claimed in claim 12,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

19. The coupling coil as claimed in claim 17,
wherein the at least one first spiral coil is wound in a first direction from the first terminal electrode to the second terminal electrode, and
wherein the at least one second spiral coil is wound in a second direction opposite to the first direction from the fourth terminal electrode to the third terminal electrode.

20. The stacked coupling coil as claimed in claim 18,
wherein the at least one third spiral coil is wound in the first direction from the first terminal electrode to the second terminal electrode, and
wherein the at least one fourth spiral coil is wound in the second direction from the fourth terminal electrode to the third terminal electrode.

21. The stacked coupling coil as claimed in claim 19,
wherein the at least one third spiral coil is wound in the first direction from the first terminal electrode to the second terminal electrode, and
wherein the at least one fourth spiral coil is wound in the second direction from the fourth terminal electrode to the third terminal electrode.

22. The stacked coupling coil as claimed in claim 20,
wherein the at least one third spiral coil is wound in the first direction from the first terminal electrode to the second terminal electrode, and
wherein the at least one fourth spiral coil is wound in the second direction from the fourth terminal electrode to the third terminal electrode.

23. The stacked coupling coil as claimed in claim 21,
wherein the at least one third spiral coil is wound in the first direction from the first terminal electrode to the second terminal electrode, and
wherein the at least one fourth spiral coil is wound in the second direction from the fourth terminal electrode to the third terminal electrode.

24. The stacked coupling coil as claimed in claim 22,
wherein the at least one third spiral coil is wound in the first direction from the first terminal electrode to the second terminal electrode, and
wherein the at least one fourth spiral coil is wound in the second direction from the fourth terminal electrode to the third terminal electrode.

25. The stacked coupling coil as claimed in claim 23,
wherein the at least one third spiral coil is wound in the first direction from the first terminal electrode to the second terminal electrode, and
wherein the at least one fourth spiral coil is wound in the second direction from the fourth terminal electrode to the third terminal electrode.

26. A circuit board comprising:
a substrate having first and second signal lines and a ground pattern; and
a coupling coil as claimed in claim 14 and mounted on the substrate,
wherein the first and fourth terminal electrodes of the coupling coil are connected respectively to first and second signal lines, and
wherein the second and third terminal electrodes of the coupling coil are connected in common to the ground pattern through a capacitor.

27. A circuit board comprising:
a substrate having first and second signal lines and a ground pattern; and
a coupling coil as claimed in claim 20 and mounted on the substrate,
wherein the first and fourth terminal electrodes of the coupling coil are connected respectively to first and second signal lines, and
wherein the second and third terminal electrodes of the coupling coil are connected in common to the ground pattern through a capacitor.
